(19) United States
(12) Patent Application Publication
(10) Pub. No.: US 2005/0045090 A1
(43) Pub. Date: Mar. 3, 2005

(54) Apparatus for laser beam machining, machining mask, method for laser beam machining, method for manufacturing a semiconductor device and semiconductor device

(76) Inventors: Hiroshi Ikegami, Kanagawa (JP); Makoto Sekine, Kanagawa (JP)

Correspondence Address: Finnegan, Henderson, Farabow,;Garrett & Dunner, L.L.P., 1300 I Street, N.W., Washington, DC, 20005-3315, US

(21) Appl. No.: 10/752,540

(22) Filed: Jan. 8, 2004

(30) Foreign Application Priority Data
Sep. 1, 2003 (JP) P2003-309338

(51) Int. Cl. C30B 28/02

(52) U.S. Cl. 117/8

(57) ABSTRACT

An apparatus for laser beam machining includes a scanning system configured to move an object in a scanning direction from a first edge of the object to another edge of the object; a beam shaping unit configured to convert a laser beam to an asymmetrical machining laser beam in the scanning direction on a plane orthogonal to an optical axis of the laser beam; and an irradiation optical system configured to irradiate the machining laser beam emitted from the beam shaping unit onto the object.

### CROSS REFERENCE TO RELATED APPLICATIONS

This application is based upon and claims the benefit of priority from prior Japanese Patent Application P2003-309338 filed on Sep. 1, 2003; the entire contents of which are incorporated by reference herein.

### BACKGROUND OF THE INVENTION

1. Field of the Invention

The present invention relates to laser beam machining, more particularly to an apparatus for laser beam machining, which controls dicing by the shape of a laser beam, a machining mask, a semiconductor device, a method for laser beam machining and a method for manufacturing a semiconductor device.

2. Description of the Related Art

In recent years, in a semiconductor device, a low dielectric constant (low-k) dielectric film has been used to enable operations at higher speed by reducing inter-wiring capacitance. However, when dicing is performed by use of a blade on the semiconductor device having the low-k dielectric film as an interlevel dielectric film, the interlevel dielectric film is peeled off.

For example, on a silicon (Si) substrate, on which the semiconductor device is fabricated, a multilevel structure is stacked, which includes a low-k dielectric film such as an organic silicon oxide film and a porous silicon oxide film, a diffusion barrier film preventing a copper (Cu) diffusion by use of such as silicon carbide (SiC), silicon nitride (Si₃N₄), silicon carbide nitride (SiCN), a silicon oxide (SiO₂) film, a polyimide film or the like. When the Si substrate having the multilevel film formed thereon is diced by use of a blade, peeling easily occurs, due to poor adhesion, from an interface of the SiC film, the Si₃N₄ film, the SiCN film or the like. Moreover, cracks occur in the low-k dielectric film, such as the organic silicon oxide film and the porous silicon oxide film, because mechanical strength of the low-k dielectric film is poor.

In order to prevent peeling of the dielectric film, there is a known machining method by which an Si substrate is diced by use of a blade after removing an interlevel dielectric film by laser irradiation. Furthermore, a method is disclosed where not only the dielectric film but also the Si substrate is diced by laser beam machining (refer to Japanese Patent Laid-Open No. 2002-224878).

A laser beam on a target surface of an object to be processed in a current apparatus for laser beam machining has a circular shape, a square shape or the like, which is symmetrical in a scanning direction of the laser beam. In laser beam machining, a machining trench is formed in the object by scanning the object with a pulse-oscillating laser beam.

For example, the Si substrate is diced by the laser beam machining and semiconductor chips are fabricated. In the Si substrate having a multilevel film thereon formed including a low-k dielectric film and a diffusion barrier film, an irradiated laser beam is transmitted through the low-k dielectric film and absorbed at the diffusion barrier film, an interface between the low-k dielectric film and the diffusion barrier film or the Si substrate. The diffusion barrier film or the Si substrate is ablated by the absorbed laser beam and the upper low-k dielectric film is removed.

However, in current laser beam machining, the ablation of the diffusion barrier film or the Si substrate provides a stress on the low-k dielectric film and cracks are generated in the low-k dielectric film.

The cracks generated in front of the scanning direction of the irradiated laser beam do not cause problems because the low-k dielectric film in front of the scanning direction is removed by the laser beam machining. However, the cracks formed in a direction orthogonal to the scanning direction are left in the semiconductor chips after the laser beam machining.

As described above, by use of the current laser beam machining method, the peeling of the dielectric film can be suppressed. However, the generation of cracks in the low-k dielectric film cannot be suppressed, which leads to a problem of low reliability of a device so fabricated. Moreover, on a dicing line, an alignment mark is formed by use of metal or the like below the dielectric film. When removing the dielectric film on the alignment mark, the peeling of the dielectric film occurs from the periphery of the alignment mark.

Moreover, when the Si substrate is diced by use of a blade, it is difficult to suppress generation of cracks in the Si substrate. Consequently, the generated cracks may cause a decrease in chip strength associated with thinning of the semiconductor chips. Moreover, in order to perform processing of the Si substrate with high precision by laser beam machining, it is required to provide a focal depth of the irradiated laser beam larger than a thickness of the Si substrate. However, if the focal depth is increased, laser beam narrowing is limited and the laser beam machining becomes difficult.

Furthermore, when a semiconductor substrate of gallium phosphide (GaP), gallium nitride (GaN) and the like or a sapphire substrate, having a semiconductor light emitting element, is diced by use of a blade, a crushed layer is formed around a dicing region. The crushed layer absorbs a light emitted from the semiconductor light emitting element and decreases the luminous efficiency. Thus, the crushed layer is removed by wet etching. The removal of the crushed layer by wet etching increases the loss of the effective area for the substrate and decreases production yield of the semiconductor light emitting element. Moreover, in order to improve the luminous efficiency, sidewalls of the semiconductor light emitting element may be inclined between upper and lower electrode formation layers by use of an angled blade. Consequently, for the semiconductor light emitting element, multiple dicing steps are required, which is inefficient.

### SUMMARY OF THE INVENTION

A first aspect of the present invention inheres in an apparatus for laser beam machining including a scanning system configured to move an object in a scanning direction from a first edge of the object to another edge of the object; a beam shaping unit configured to convert a laser beam to an asymmetrical machining laser beam in the scanning direction on a plane orthogonal to an optical axis of the laser beam; and an irradiation optical system configured to irradiate the machining laser beam emitted from the beam shaping unit onto the object.

A second aspect of the present invention inheres in a machining mask for converting a shape of a laser beam for laser beam machining of an object by scanning the laser beam on a plane orthogonal to an optical axis of the laser beam including an opaque portion having a vertical opaque portion disposed vertically to the optical axis and an inclined opaque portion inclined to a plane of the vertical opaque portion; a first machining opening which provides an opening in the vertical opaque portion; and a second machining opening which provides an opening connected to the first machining opening in the inclined opaque portion so as to extend in a direction opposite to the first machining opening.

A third aspect of the present invention inheres in a method for laser beam machining including converting a laser beam to an asymmetrical machining laser beam in a first direction; projecting the machining laser beam onto an object; scanning the machining laser beam on a surface of the object in a scanning direction corresponding to the first direction.

A fourth aspect of the present invention inheres in a method for manufacturing a semiconductor device including depositing a dielectric film on a front surface of a semiconductor substrate; projecting a machining laser beam onto the semiconductor substrate, the machining laser beam being obtained by converting a laser beam to an asymmetric shape in a first direction; scanning the machining laser beam on the front surface of the semiconductor substrate in a scanning direction corresponding to the first direction; and forming a dicing region in the scanning direction by removing the dielectric film.

A fifth aspect of the present invention inheres in a semiconductor device including a semiconductor substrate; a plurality of interlevel dielectric films deposited on a surface of the semiconductor substrate; and a diffusion barrier film deposited between the plurality of interlevel dielectric films and having a region reformed so as to increase adhesion strength between the diffusion barrier film and the interlevel dielectric films in the vicinity of a chip periphery.

### BRIEF DESCRIPTION OF THE DRAWINGS

FIG. 1 is a schematic block diagram of an apparatus for laser beam machining according to an embodiment of the present invention;

FIG. 2 is a plan view schematically showing one example of a machining mask according to a first embodiment of the present invention;

FIG. 3 is a view showing a cross-sectional structure of an example of a semiconductor substrate according to the first embodiment of the present invention;

FIG. 4 is a plan view schematically showing a position of a machining laser beam before laser beam machining of the semiconductor substrate according to the first embodiment of the present invention;

FIG. 5 is a plan view schematically showing a case where a dicing region is formed by laser beam machining in the semiconductor substrate according to the first embodiment of the present invention;

FIG. 6 is a schematic view of a cross-section VI-VI of FIG. 5 where the dicing region is formed by laser beam machining in the semiconductor substrate according to the first embodiment of the present invention;

FIG. 7 is a schematic view of a cross-section at VII-VII line in FIG. 5 where the dicing region is formed by laser beam machining in the semiconductor substrate according to the first embodiment of the present invention;

FIG. 8 is a schematic view of a cross-section at VIII-VIII line in FIG. 5 where the dicing region is formed by laser beam machining in the semiconductor substrate according to the first embodiment of the present invention;

FIG. 9 is a schematic view of a cross-section at IX-IX line in FIG. 5 where the dicing region is formed by laser beam machining in the semiconductor substrate according to the first embodiment of the present invention;

FIGS. 10A to 10E are plan views schematically showing other examples of the machining mask according to the first embodiment of the present invention;

FIG. 11 is a schematic view showing an example of a machining mask according to a second embodiment of the present invention;

FIGS. 12A and 12B are schematic views showing an example of a beam shaping unit according to the second embodiment of the present invention;

FIG. 13 is a view showing an example of a projected image of a machining laser beam of laser beam machining according to the second embodiment of the present invention;

FIGS. 14 to 16 are examples of the cross-sectional views for explaining the laser beam machining for a semiconductor substrate according to the second embodiment of the present invention;

FIGS. 17A to 17F are plan views schematically showing other examples of the machining mask according to the second embodiment of the present invention;

FIG. 18 is a plan view schematically showing an example of a machining mask according to a third embodiment of the present invention;

FIG. 19 is a view showing an example of a projected image of a machining laser beam of laser beam machining according to the third embodiment of the present invention;

FIGS. 20 to 22 are examples of the cross-sectional views for explaining the laser beam machining for a semiconductor substrate according to the third embodiment of the present invention;

FIG. 23 is a schematic view of a cross-section after laser beam machining for another semiconductor substrate by use of the machining mask according to the third embodiment of the present invention;

FIG. 24 is a plan view schematically showing an example of a machining mask according to a fourth embodiment of the present invention;

FIG. 25 is a view showing a relationship between a machining mask position and a focus position in a laser beam machining apparatus according to the fourth embodiment of the present invention;

FIG. 26 is a schematic view showing an example of disposition of the machining mask according to the fourth embodiment of the present invention;

FIG. 27 is a view showing a position of a projected image of a machining laser beam of laser beam machining according to the fourth embodiment of the present invention;

FIGS. 28 to 31 are examples of the cross-sectional views for explaining the laser beam machining for a semiconductor substrate according to the fourth embodiment of the present invention;

FIG. 32 is a schematic view showing an example of an irradiation optical system according to a modification of the fourth embodiment of the present invention;

FIG. 33 is a view showing a position of a projected image of a machining laser beam of laser beam machining according to the modification of the fourth embodiment of the present invention;

FIG. 34 is a plan view schematically showing an example of a machining mask according to a fifth embodiment of the present invention;

FIG. 35 is a view showing an example of a projected image of a machining laser beam of laser beam machining according to the fifth embodiment of the present invention; and

FIGS. 36 to 39 are examples of the cross-sectional views for explaining the laser beam machining for a semiconductor substrate according to the fifth embodiment of the present invention.

### DETAILED DESCRIPTION OF EMBODIMENTS

Various embodiments of the present invention will be described with reference to the accompanying drawings. It is to be noted that the same or similar reference numerals are applied to the same or similar parts and elements throughout the drawings, and the description of the same or similar parts and elements will be omitted or simplified.

(First Embodiment)

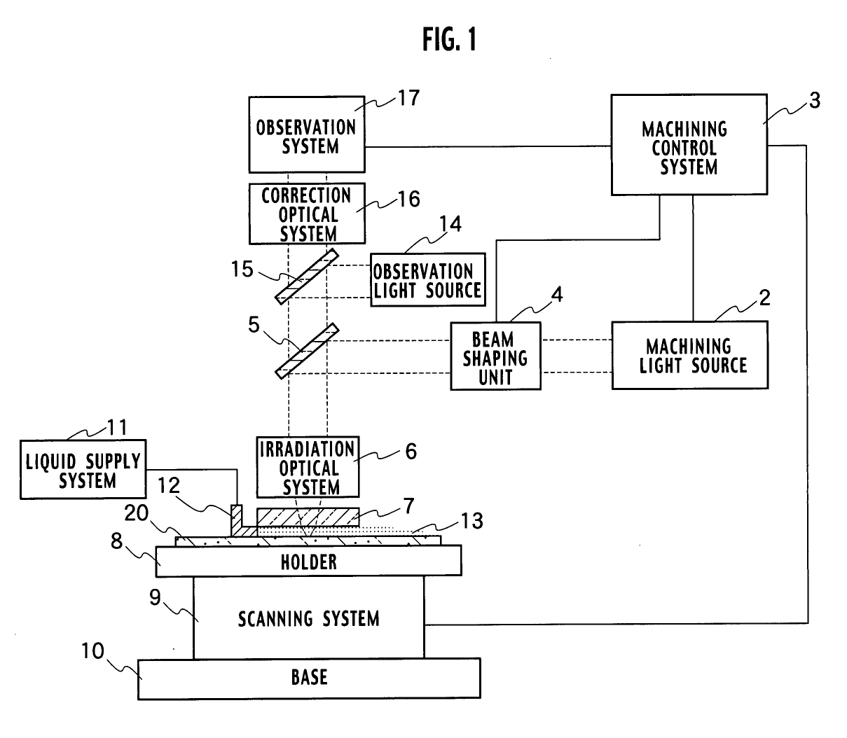

As shown in FIG. 1, an apparatus for laser beam machining according to a first embodiment of the present invention includes a scanning system 9 configured to move an object 20 to be machining, disposed on a holder 8, in a scanning direction from one end of the object 20 toward the other end thereof. A beam shaping unit 4 includes a machining mask having an asymmetric shaped opening extending in a direction corresponding to the scanning direction of the scanning system 9 on a plane orthogonal to an optical axis direction of a laser beam from a machining light source 2 and includes an optical system so as to output the laser beam which is converted into the asymmetric shape. An irradiation optical system 6 is configured to irradiate the laser beam, which is incident through a half mirror 5 from the beam shaping unit 4, onto the object 20 through a transparent window 7. The scanning system 9 is provided on a base 10.

In the first embodiment, as the machining light source 2, for example, the third harmonic of a Q-switch neodymium doped yttrium aluminum garnet (Nd:YAG) laser is used, which has a wavelength of 355 nm, a pulse width of approximately 30 ns and an oscillation frequency of 50 kHz at the maximum. For the irradiation optical system 6, an objective lens having a focal length f of 50 mm is used. An optical path length between the objective lens and the beam shaping unit 4 is approximately 300 mm. A reduction projection ratio of the irradiation optical system 6 is ⅕.

Moreover, between a target surface of the object 20 and the transparent window 7, a liquid supply system 11 is provided which supplies a liquid 13 such as water through a nozzle 12. Machining dust produced in processing a dielectric film and the like is removed by the flow of the liquid 13. Thus, processing the dielectric film can be achieved without adhesion of the machining dust onto another portion of the surface of the object 20. In the case of implementing a cleaning step by scrubber cleaning or the like after the laser beam machining, it is not particularly necessary to perform the laser beam machining in the liquid 13. The laser beam machining may be conducted in the atmosphere. Moreover, dispersion of heat generated by laser irradiation can be prevented by the liquid 13 on the target surface of the object 20. In FIG. 1, the liquid 13 flows over the surface of the object 20 and scatters in many different directions. However, the liquid 13 may be introduced into a vessel having an appropriate outlet port. Moreover, the liquid 13 may be circulated from the outlet port through a filter to the liquid supply system 11. As the liquid 13, other than water, aerated water, ozonated water, an ammonia (NH₃) solution, a mixture of glycine (C₂H₅NO₂) and hydrogen peroxide (H₂O₂) or the like can be used.

Furthermore, the apparatus for laser beam machining includes an observation light source 14, such as a halogen lamp, so as to irradiate an observation light onto the target surface of the object 20 through a half mirror 15 and the half mirror 5 for detecting a machining position of the object 20, a correction optical system 16 configured to implement focus adjustment of the observation light incident through the half mirrors 5, 15 reflected from the target surface of the object 20, and an observation system 17 configured to permit observation of the position of the object 20 subjected to the focus adjustment by the correction optical system 16.

A machining control system 3 controls the machining light source 2 so as to output the laser beam by position information of the object 20, which is provided from the observation system 17. Moreover, by the position information provided from the observation system 17, the machining control system 3 can finely adjust a projection position of the beam shaping unit 4 on the target surface of the object 20.

As the object 20, for example, a semiconductor substrate 20 such as an Si substrate is used. On the semiconductor substrate 20 having a circuit pattern formed thereon, dielectric films such as a low-k dielectric film, a diffusion barrier film, a SiO₂ film and a polyimide film are formed. In the first embodiment, description will be given of a case where a dicing region is formed by removing the dielectric films deposited on the semiconductor substrate 20.

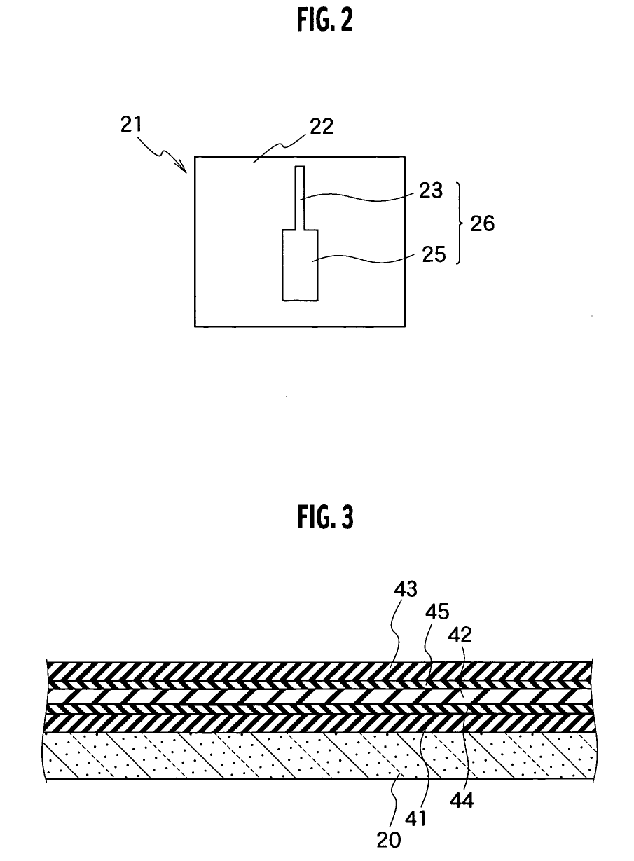

As shown in FIG. 2, in a machining mask 21 provided in the beam shaping unit 4, a region machining opening 26 is provided, which includes a slit 23 providing an opening in an opaque portion 22 made of stainless steel or the like, and a rectangular shaped transparent region 25 having a side wider than a width of the slit 23 and being connected to one end of the slit 23. The machining mask 21 may be fabricated by patterning an opaque film made of chromium (Cr) or the like, which is deposited on a quartz substrate, by use of photolithography or the like.

The machining mask 21 is placed, for example, perpendicular to the optical axis of the laser beam in the beam shaping unit 4 so as to locate the slit 23 on an upper side in FIG. 2. In addition, the machining mask 21 is placed in the beam shaping unit 4 so that a leading end of a projected image of the laser beam transferred through the slit 23 of the machining mask 21 can illuminate the semiconductor substrate 20, and can face the scanning direction of the semiconductor substrate 20.

The machining mask 21 has a thickness of 50 μm, for example. On the semiconductor substrate 20, a width of the slit 23 is 10 μm and a width of the transparent region 25 is 50 μm to 80 μm which corresponds to a width of the dicing region. Lengths of both the slit 23 and the transparent region 25 are 10 μm to 100 μm on the semiconductor substrate 20. Note that dimensions of the pattern on the machining mask 21 will be described below in terms of dimensions subjected to reduction projection on the semiconductor substrate 20, unless otherwise noted.

A scanning speed of the scanning system 9 for the semiconductor substrate 20 is 100 mm/s. The oscillation frequency of the laser beam from the machining light source 2 is 50 kHz and an irradiation fluence is 0.6 J/cm²/pulse. Here, an “irradiation fluence” is defined as an irradiation energy density per pulse. Note that the scanning speed of the semiconductor substrate 20, the oscillation frequency of the laser beam, the irradiation fluence and the like are appropriately controlled so as to ablate the dielectric films in accordance with a film structure of the semiconductor substrate 20.

In the first embodiment, as shown in FIG. 3, for example, a first dielectric film 41, a first diffusion barrier film 44, a second dielectric film 42, a second diffusion barrier film 45 and a third dielectric film 43 are sequentially laminated on a surface of the semiconductor substrate 20 where the dicing region is formed. For example, the first to third dielectric films 41 to 43 may be used as interlevel dielectric films of a semiconductor device fabricated on the semiconductor substrate.

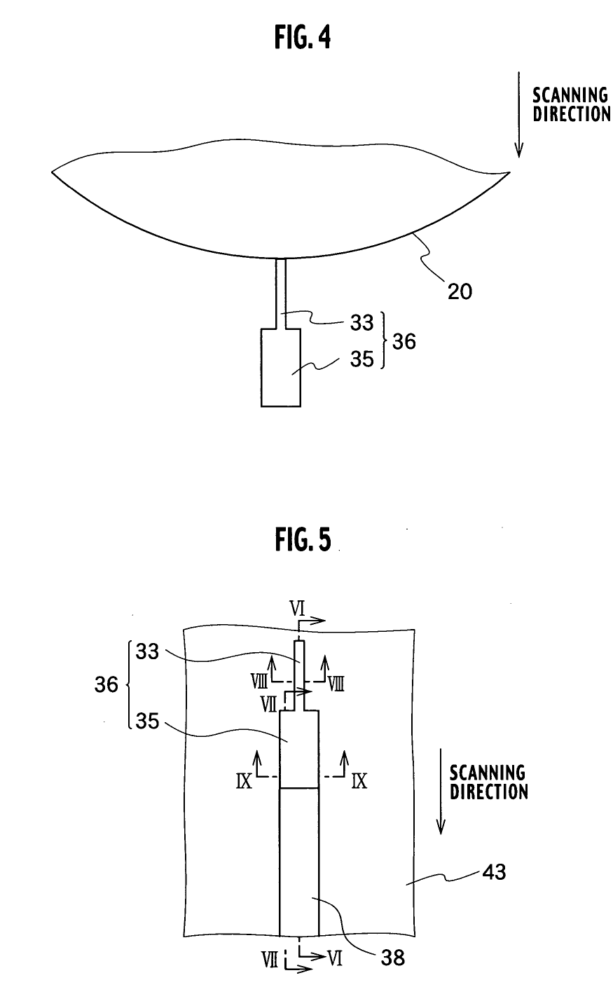

As shown in FIG. 4, through the region machining opening 26 of the machining mask 21, the laser beam forms a machining laser beam 36 which includes a first region machining laser beam 33 having a narrow stripe shape corresponding to the slit 23 and a second region machining laser beam 35 having a rectangular shape corresponding to the transparent region 25. By the machining control system 3, the machining laser beam 36 is provided so as to position a leading end of the first region machining laser beam 33 at an end portion of the semiconductor substrate 20 facing the scanning direction. When the semiconductor substrate 20 is moved in the scanning direction by the scanning system 9, the machining laser beam 36 is projected onto the semiconductor substrate 20.

Here, the first to third dielectric films 41 to 43 are low-k dielectric films with a relative dielectric constant of approximately 3.4 or less and are transparent to the laser beam. Moreover, the irradiation fluence of the laser beam is 0.6 J/cm², so that the first and second diffusion barrier films 44, 45 can be ablated. In addition, in the case of ablation of the semiconductor substrate 20, melting for ablation occurs only in the vicinity of the surface of the semiconductor substrate 20. Thus, a trench is hardly formed in the semiconductor substrate 20.

First, by the laser beam of the first region machining laser beam 33 through the third dielectric film 43 shown in FIGS. 2 and 3, the second diffusion barrier film 45 is ablated and the third dielectric film 43 on the ablated second diffusion barrier film 45 is removed together. Subsequently, in a portion where the second diffusion barrier film 45 has been ablated, the laser beam of the first region machining laser beam 33 is irradiated on the first diffusion barrier film 44 through the second dielectric film 42. Then the first diffusion barrier film 44 is ablated and the second dielectric film 42 on the ablated first diffusion barrier film 44 is removed. In a portion where the first diffusion barrier film 44 has been ablated, the laser beam of the first region machining laser beam 33 is irradiated to the surface of the semiconductor substrate 20 through the first dielectric film. Then, the semiconductor substrate 20 is ablated and the first dielectric film 41 on the ablated semiconductor substrate 20 is removed.

The first to third dielectric films 41 to 43 undergo a stress due to the heat generated by the ablation and by a gas pressure of the first and second diffusion barrier films 44, 45 or the semiconductor substrate 20 which are vaporized. Thus, cracks are generated by the stress in the first to third dielectric films 41 to 43 around the irradiated region of the first region machining laser beam 33. The cracks generated in front of the scanning direction may be removed by the laser beam machining by scanning of the semiconductor substrate 20. The cracks generated in a direction orthogonal to the scanning direction around the irradiated region of the first region machining laser beam 33 are removed by the second region machining laser beam 35 having a larger width than the first region machining laser beam 33. In ablation performed by the second region machining laser beam 35, a narrow trench is already formed by the first region machining laser beam 33. Thus, a stress on the low-k dielectric films of the first to third dielectric films 41 to 43 is reduced and the generation of cracks in the direction orthogonal to the scanning direction can be suppressed.

In the apparatus for laser beam machining according to the first embodiment of the present invention, the machining mask 21 is used, which includes the region machining opening 26 having the slit 23 for machining the narrow trench and the transparent region 25 for removing cracks generated by the narrow trench machining in the low-k dielectric films. Therefore, the dicing region can be formed by removing the interlevel dielectric films of the semiconductor device deposited on the semiconductor substrate 20, so that occurrence of peeling and cracks in the interlevel dielectric films can be suppressed.

Next, a method for laser beam machining according to the first embodiment of the present invention will be described with reference to FIGS. 1 to 9. First, a semiconductor substrate (an object) 20 shown in FIG. 3 is fixed on the holder 8 of the laser beam machining apparatus shown in FIG. 1 by use of a dicing tape and the like. The observation light of the observation light source 14 is irradiated to adjust focusing by the correction optical system 16 and a position of the semiconductor substrate 20 is detected by the observation system 17. From the position information of the semiconductor substrate 20, which is provided from the observation system 17, the machining control system 3 controls the scanning system 9 to move the semiconductor substrate 20, so that an edge portion of the semiconductor substrate 20 is within a field of view of the observation system 17. The machining mask 21 shown in FIG. 2 is placed in the beam shaping unit 4 and oscillation of the machining light source 2 is implemented by the machining control system 3. The laser beam passing through the machining mask 21 of the beam shaping unit 4 is projected on the holder 8 by the irradiation optical system 6. While observing the projected machining laser beam 36 through the observation system 17, the scanning system 9 is operated by the machining control system 3 so as to position the edge portion of the semiconductor substrate 20 at the leading end of the first region machining laser beam 33, as shown in FIG. 4.

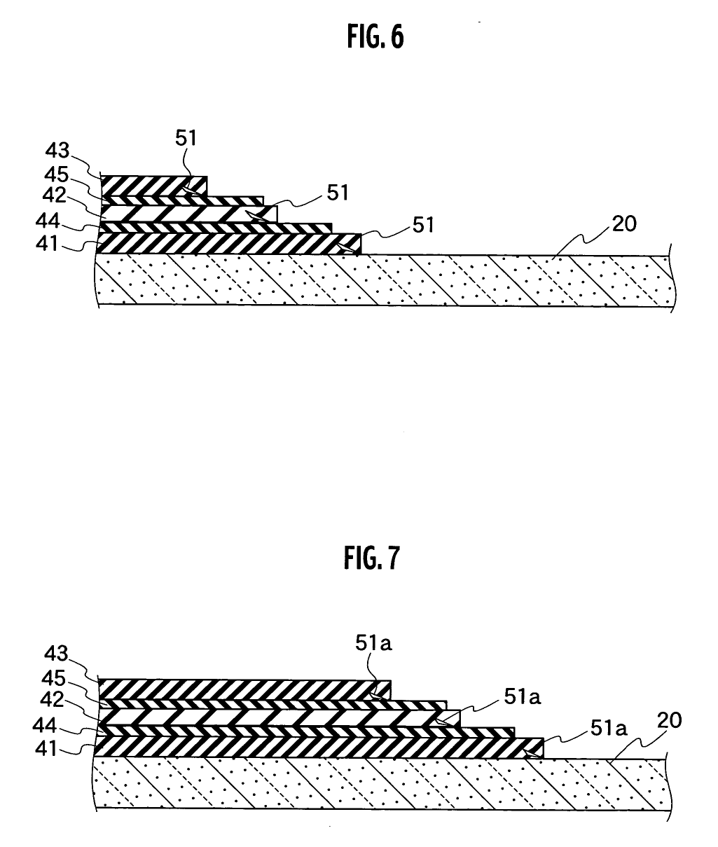

As shown in FIG. 5, by scanning the semiconductor substrate 20, a dicing region 38 is progressively formed by laser beam machining. The cross-section at line VI-VI of the drawing along the scanning direction from the leading end of the first region machining laser beam 33 of the machining laser beam 36 to the processed dicing region 38 is, as shown in FIG. 6, formed in a stepped shape. This is because ablation caused by irradiation of the first region machining laser beam 33 sequentially removes the first to third dielectric films 41 to 43 and the first and second diffusion barrier films 44 and 45 in the scanning direction. For example, in the vicinity of the leading end of the first region machining laser beam 33, the third dielectric film 43 is removed and the second diffusion barrier film 45 is partially exposed. In an end portion of the second diffusion barrier film 45 in the scanning direction, the second dielectric film 42 is exposed. Moreover, in an end portion of the second dielectric film 42 in the scanning direction, the first diffusion barrier film 44 is exposed. In an end portion of the first diffusion barrier film 44 in the scanning direction, the first dielectric film 41 is exposed. In the first region machining laser beam 33 at a part of the second region machining laser beam 35, the surface of the semiconductor substrate 20 is exposed. In processed ends of the first to third dielectric films 41 to 43, first cracks 51 are generated due to stress caused by ablation from portions contacting the surfaces of the first and second diffusion barrier films 44, 45 and the semiconductor substrate 20 which underlie the first to third dielectric films 41 to 43, respectively.

Moreover, similar to the above-described first region machining laser beam 33, the cross-section at line VII-VII of the drawing along the scanning direction from a leading end of the second region machining laser beam 35 toward the machined dicing region 38 is also formed in a stepped shape as shown in FIG. 7. This is because ablation caused by irradiation of the second region machining laser beam 35 sequentially removes the third dielectric film 43, the second diffusion barrier film 45, the second dielectric film 42, the first diffusion barrier film 44 and the first dielectric film 41 in the scanning direction. As a result, the surface of the semiconductor substrate 20 is exposed. Also in FIG. 7, in processed ends of the first to third dielectric films 41 to 43, first cracks 51a are similarly generated due to the stress caused by the ablation from portions contacting the surfaces of the first and second diffusion barrier films 44, 45 and the semiconductor substrate 20 which underlie the first to third dielectric films 41 to 43, respectively. Since the first region machining laser beam 33 removes the first to third dielectric films 41 to 43 and the first and second diffusion barrier films 44 and 45 so as to form the machined region, the stress caused by the ablation is reduced. Therefore, the first cracks 51a are smaller than the first cracks 51 shown in FIG. 6.

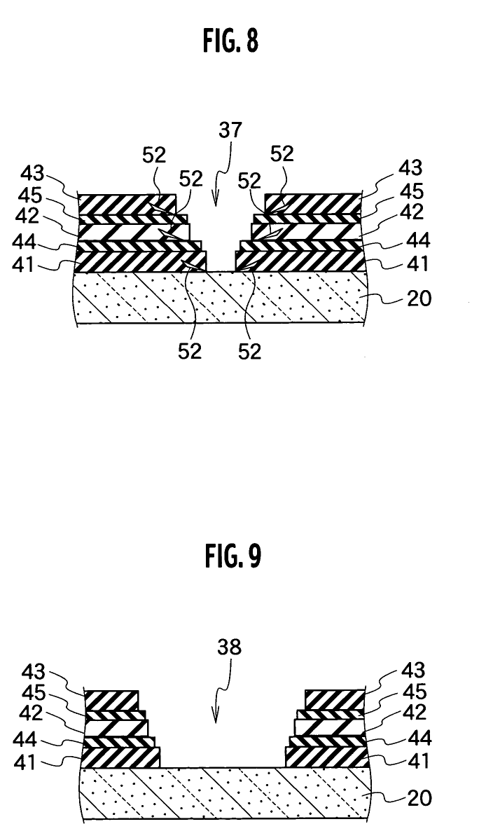

In the cross-section at line VIII-VIII of the drawing in a direction orthogonal to the scanning direction in an area away from the leading end of the first region machining laser beam 33 and close to the second region machining laser beam 35, as shown in FIG. 8, a narrow dicing region 37 is formed, where the surface of the semiconductor substrate 20 is exposed. This is because the ablation caused by the irradiation of the first region machining laser beam 33 removes the third dielectric film 43, the second diffusion barrier film 45, the second dielectric film 42, the first diffusion barrier film 44 and the first dielectric film 41. The ablation occurs sequentially from the second diffusion barrier film 45, the first diffusion barrier film 44 to the surface of the semiconductor substrate 20. Thus, the narrow dicing region 37 has an inclined opening which is wider at the surface of the third dielectric film 43. Also in the direction orthogonal to the scanning direction of FIG. 8, in processed ends of the first to third dielectric films 41 to 43, second cracks 52 are similarly generated due to the stress caused by the ablation from portions contacting the surfaces of the first and second diffusion barrier films 44, 45 and the semiconductor substrate 20 which underlie the first to third dielectric films 41 to 43, respectively.

In the cross-section at line IX-IX of the drawing along the direction orthogonal to the scanning direction in a lower part of the second region machining laser beam 35, as shown in FIG. 9, the dicing region 38 is formed, where the surface of the semiconductor substrate 20 is exposed. This is because ablation of the first and second diffusion barrier films 44 and 45 and the semiconductor substrate 20, due to the irradiation of the second region machining laser beam 35, removes the third dielectric film 43, the second diffusion barrier film 45, the second dielectric film 42, the first diffusion barrier film 44 and the first dielectric film 41. In the laser beam machining of the second region machining laser beam 35, the narrow dicing region 37 is already formed and the second cracks 52 are generated in the first to third dielectric films 41 to 43. In the region removed by ablation in the second region machining laser beam 35, the stress is already reduced to some extent. Moreover, the first to third dielectric films 41 to 43 are removed so as to have open ends. Thus, vaporization pressure due to the ablation can be escaped from the open ends and the stress can be suppressed. Therefore, by the laser beam machining of the dicing region 38, the second cracks 52 generated adjacent to the narrow dicing region 37 of the first to third dielectric films 41 to 43 can be removed and the processed ends can be formed without cracks.

As described above, by use of the laser beam machining apparatus according to the first embodiment, the dicing region 38 can be formed while suppressing the generation of cracks in the processed ends of the first to third dielectric films 41 to 43, which are interlevel low-k dielectric films. After forming the dicing region 38, the semiconductor substrate 20 is diced by use of a blade having a width narrower than the width of the dicing region. Thus, peeling of the interlevel dielectric films and cracks generated therein can be suppressed and a semiconductor device with high reliability can be manufactured. Moreover, it is needless to say that the dicing of the semiconductor substrate 20 can also be implemented by use of the laser beam machining apparatus.

Moreover, if the liquid 13, such as water, is supplied from the liquid supply system 11 to the target surface of the semiconductor substrate 20 during machining of the interlevel dielectric films, not only the machining dust can be removed but also dispersion of heat generated in the region of the laser beam machining is prevented. Therefore, it is effective in reducing the stress to supply the liquid 13 during the laser beam machining.

The machining mask 21 according to the first embodiment implements shaping of the machining laser beam in the region machining opening 26 having the slit 23 and the transparent region 25, in order to reduce the stress of the interlevel dielectric films. However, for a region machining opening of a machining mask for reducing the stress of the interlevel dielectric films, various shapes are applicable. For example, in a machining mask 21a, as shown in FIG. 1A, a region machining opening 26a is provided, which includes an intermediate transparent portion 24 between the slit 23 and the transparent region 25. The width of the intermediate transparent portion 24 is wider than the width of the slit 23 and narrower than the width of the transparent region 25. Therefore, removal of cracks and a stress portion, which are generated in the interlevel dielectric films in the direction orthogonal to the scanning direction by ablation due to the first region machining laser beam 33 irradiated after passing through the slit 23, is achieved in stages by the laser beam passing through the intermediate transparent portion 24 and the transparent region 25. Therefore, the dicing region 38 can be formed so as to suppress further effectively the generation of cracks in the processed ends of the interlevel dielectric films.

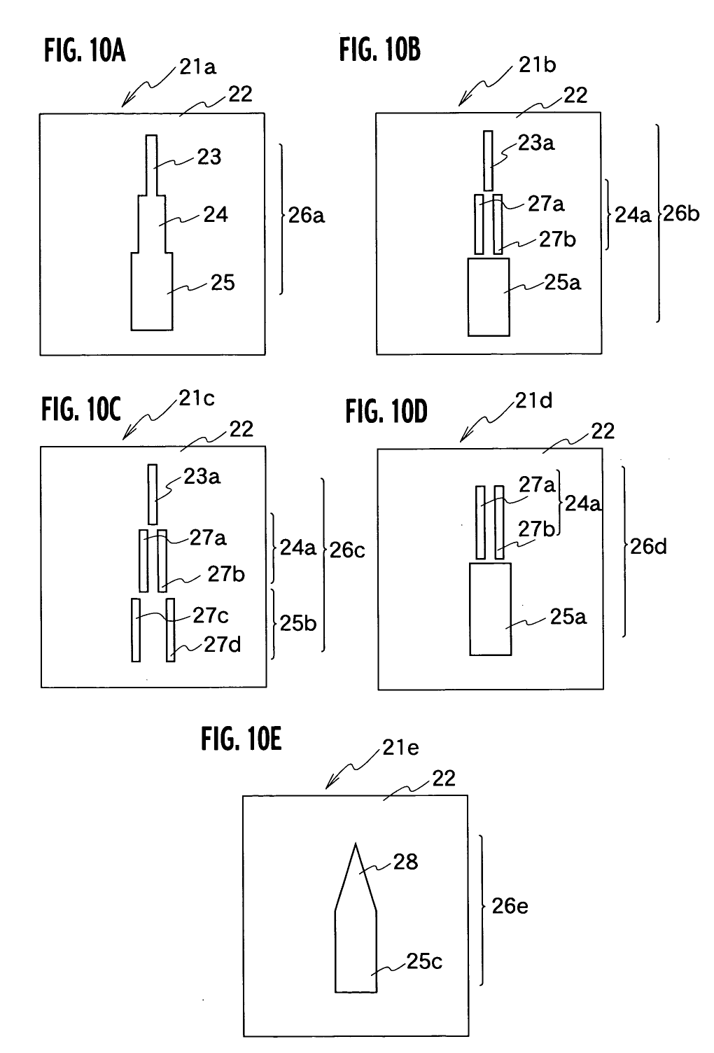

The intermediate transparent portion 24 may be formed only by removing the processed ends of the interlevel dielectric films in the narrow dicing region 37. For example, in a machining mask 21b, as shown in FIG. 10B, a region machining opening 26b is provided, which includes a slit 23a forming the narrow dicing region 37, an intermediate transparent portion 24a having slits 27a and 27b facing each other, and a transparent region 25a. Inner edges of the slits 27a and 27b of the intermediate transparent portion 24a, facing each other, are on lines of both edges of the slit 23a in a longitudinal direction. Moreover, a width between outer edges of the slits 27a and 27b, facing each other, is narrower than a width of the transparent region 25a. Each of the slits 27a and 27b of the intermediate transparent portion 24a partially removes the cracks and the stress portion, which are generated in the interlevel dielectric films in the direction orthogonal to the scanning direction by ablation due to irradiation of the first region machining laser beam 33 passing through the slit 23a. Therefore, the cracks and the stress portion, which are generated in the interlevel dielectric films in the direction orthogonal to the scanning direction, is removed step-by-step by the laser beam passing through the intermediate transparent portion 24a and the transparent region 25a.

Moreover, in a machining mask 21c, as shown in FIG. 10C, a region machining opening 26c is provided, which includes the slit 23a, the intermediate transparent portion 24a having the slits 27a and 27b and a transparent region 25b having slits 27c and 27d. Inner edges of the slits 27c and 27d of the transparent region 25b, facing each other, are provided in line with the outer edges of the slits 27a and 27b of the intermediate transparent portion 24a. The cracks and the stress portion, which are generated in the interlevel dielectric films in the direction orthogonal to the scanning direction by the ablation due to irradiation of the first region machining laser beam 33 passing through the slit 23a, are removed step-by-step by the intermediate transparent portion 24a and the transparent region 25b. Between the slits 27a and 27b and between the slits 27c and 27d, the surface of the semiconductor substrate 20 is already exposed by the slit 23a and the intermediate transparent portion 24a. Thus, the dicing region 38 can be easily formed.

In a machining mask 21d, as shown in FIG. 10D, a region machining opening 26d including the intermediate transparent portion 24a and the transparent region 25a is provided, by omitting the slit 23a from the machining mask 21b of FIG. 10B. The cracks and the stress portion, which are generated in the interlevel dielectric films in the direction orthogonal to the scanning direction by ablation due to irradiation of the laser beam passing through the intermediate transparent portion 24a, are removed by the transparent region 25a.

Furthermore, in a machining mask 21e, as shown in FIG. 10E, a region machining opening 26e including a triangular shaped intermediate transparent portion 28 and a rectangular shaped transparent region 25c is provided. The intermediate transparent portion 28 corresponds, for example, to the slit 23 and intermediate transparent portion 24 of the machining mask 21a shown in FIG. 10A. The cracks and the stress portion, which are generated in the interlevel dielectric films in the direction orthogonal to the scanning direction by ablation due to irradiation of the laser beam passing the vicinity of the vertex of the intermediate transparent portion 28 in the leading end of the scanning direction, are gradually removed by the intermediate transparent portion 28, in which a width of the intermediate transparent portion 28 is increased in a triangular shape in the scanning direction, and the transparent region 25c.

As described above, according to the structure of the interlevel dielectric films, the machining mask which converts the laser beam into an optimum shape is appropriately selected from the machining masks 21 and 21a to 21e. Thus, the dicing region 38 can be formed so as to suppress the generation of cracks in the processed ends of the interlevel dielectric films using low-k dielectric films.

(Second Embodiment)

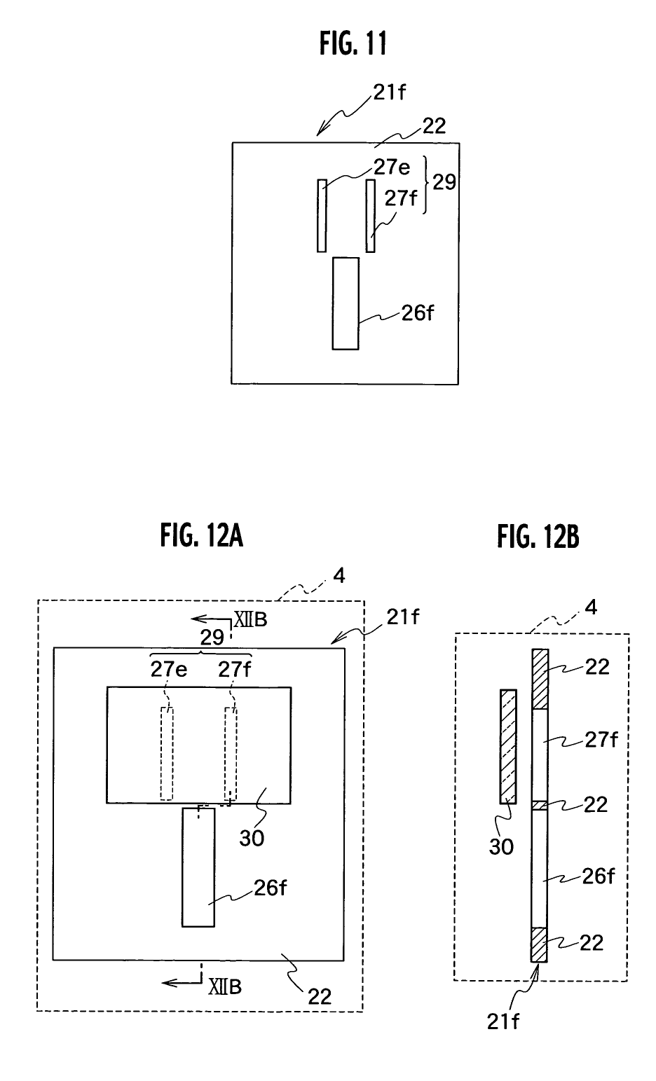

As shown in FIG. 11, a machining mask 21f according to a second embodiment of the present invention includes openings of a reforming machining opening 29, having slits 27e and 27f facing each other in the opaque portion 22, and a rectangular shaped region machining opening 26f. A longitudinal direction of the slits 27e, 27f corresponds to the scanning direction and the slits 27e, 27f are placed in a front portion of the scanning direction for the region machining opening 26f. In addition, the slits 27e, 27f are placed outside of edges of the region machining opening 26f in the direction orthogonal to the scanning direction and at positions corresponding to portions of the interlevel dielectric films having cracks and stresses, which may be generated by ablation due to the laser beam passing through the region machining opening 26f.

For example, when the laser beam is irradiated at an irradiation fluence lower than an energy level required for ablation to the diffusion barrier films of SiC, Si₃N₄, SiCN and the like, the diffusion barrier films or a state of an interface between the diffusion barrier films and adjacent interlevel dielectric films is reformed. Thus, there is substantially no peeling of the interlevel dielectric films. Therefore, by irradiating the laser beam with a low irradiation fluence, which passes through the reforming machining opening 29 of the machining mask 21f, adhesion strength between the interlevel dielectric films and the diffusion barrier films increases. Thus, in subsequently performed ablation by the laser beam passing through the region machining opening 26f, the peeling and cracks of the interlevel dielectric films can be suppressed.

In the second embodiment, for forming a dicing region, the adhesion strength between the interlevel dielectric films and the diffusion barrier films in a portion where stress is induced by ablation increases in the reforming machining opening 29 by use of the machining mask 21f and, thereafter, machining of the dicing region is implemented. The rest of the configurations are the same as the first embodiment, and thus duplicate description is omitted.

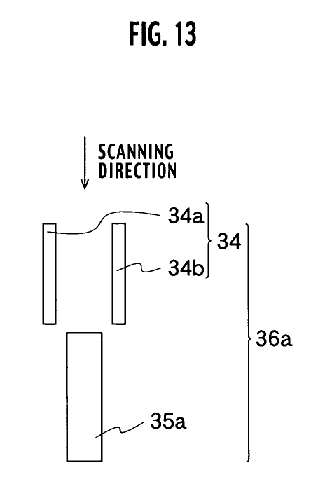

In the beam shaping unit 4 according to the second embodiment, as shown in FIG. 12A, the machining mask 21f and a light attenuator 30 cover the reforming machining opening 29 at a side for emitting the laser beam. In a cross-sectional view at line XIIB-XIIB of the drawing of the machining mask 21f and the light attenuator 30, as shown in FIG. 12B, the machining mask 21f and the light attenuator 30 are placed vertically to the optical axis of the laser beam. Here, as shown in FIG. 13, a machining laser beam 36a projected onto the object 20 through the half mirror 5 and the irradiation optical system 6 shown in FIG. 1, includes a reforming machining laser beam 34 having first and second attenuated laser beams 34a, 34b projected to face each other in front of the machining laser beam 36a in the scanning direction, and a region machining laser beam 35a projected to the rear of the reforming machining laser beam 34 along the scanning direction. Here, the intensity of the laser beam of the first and second attenuated laser beams 34a, 34b is attenuated by the light attenuators 30 and an irradiation fluence thereof is reduced. By providing a neutral density (ND) filter, for example, as the light attenuator 30, the irradiation fluence of the reforming machining laser beam 34 is reduced compared to the irradiation fluence of the region machining laser beam 35a. The region machining laser beam 35a removes the interlevel dielectric films by ablating the diffusion barrier films between the first and second attenuated laser beams 34a, 34b.

For example, when a SiCN film is used as the diffusion barrier film, the SiCN film is ablated with an irradiation fluence of 0.6 J/cm². When the irradiation fluence is reduced, for example, to half, that is 0.3 J/cm², no ablation occurs. However, the SiCN film is reformed to generate amorphous Si and amorphous carbon (C). The amorphous Si and the amorphous C contribute to improvement of adhesion intensity at an interface of adjacent interlevel dielectric films such as low-k dielectric films. Therefore, if the interlevel dielectric films are removed by ablating the diffusion barrier films in a region where the diffusion barrier films are reformed, it is possible to machine a dicing region in which cracks and peeling of the interlevel dielectric films are suppressed.

Note that, in the second embodiment, an ND filter is used as the light attenuator 30. However, in the case of using a machining mask formed by patterning an opaque film, such as a Cr film, which is deposited on a quartz substrate, transmittance may be controlled by leaving a thin layer of the opaque film as the light attenuator in a region corresponding to the reforming machining opening.

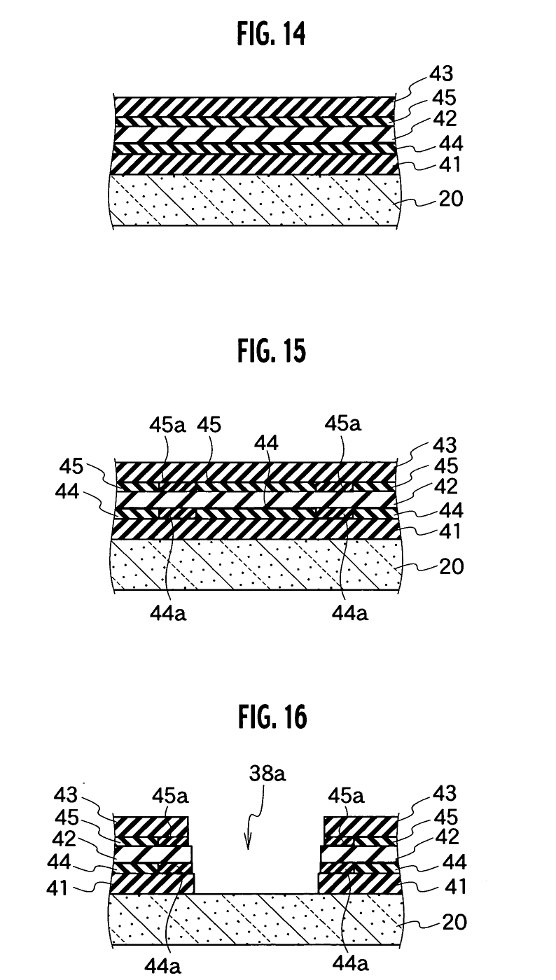

Next, a method for laser beam machining according to the second embodiment will be described with reference to FIGS. 14 to 16. The irradiation fluence of the laser beam passing through the region machining opening 26f is 0.6 J/cm². An ND filter with transmittance of 50% is provided as the light attenuator 30. Thus, the irradiation fluence of the laser beam passing through the reforming machining opening 29 is 0.3 J/cm² On a surface of a semiconductor substrate (an object) 20, a first dielectric film 41, a first diffusion barrier film 44, a second dielectric film 42, a second diffusion barrier film 45 and a third dielectric film 43 are sequentially laminated, as shown in FIG. 14.

The semiconductor substrate 20 is fixed on a holder 8 shown in FIG. 1 by use of a vacuum chuck, a electrostatic chuck and the like. A dicing tape may be used to fix the semiconductor substrate 20 on the holder 8 depending on a following process. When the semiconductor substrate 20 is scanned by a scanning system 9, first, a reforming machining laser beam 34 of a machining laser beam 36a is irradiated. The irradiated reforming machining laser beam 34 has a reduced irradiation fluence by the light attenuator 30. Thus, as shown in FIG. 15, first and second reformed diffusion barrier films 44a and 45a are formed in regions where the reforming machining laser beam 34 is irradiated in the first and second diffusion barrier films 44 and 45. The first reformed diffusion barrier films 44a are formed under the second reformed diffusion barrier films 45a, because the transmittance of the laser beam in the first reformed diffusion barrier films 44a increases so as to transmit the laser beam therefrom.

The semiconductor substrate 20 is scanned by the scanning system 9 and the region machining laser beam 35a is irradiated in the regions where the first and second reformed diffusion barrier films 44a and 45a are formed. The irradiation region of the region machining laser beam 35a is between the first reformed diffusion barrier films 44a and between the second reformed diffusion barrier films 45a, respectively, facing each other in the direction orthogonal to the scanning direction. Therefore, the first and second diffusion barrier films 44 and 45 between the first reformed diffusion barrier films 44a and between the second reformed diffusion barrier films 45a are ablated. Thus, as shown in FIG. 16, the second and third dielectric films 42 and 43 are removed. Furthermore, the first dielectric film 41 is removed by ablation in the vicinity of the surface of the semiconductor substrate 20. As a result, a dicing region 38a is formed.

In the second embodiment, an adhesion strength of interfaces of the first and second reformed diffusion barrier films 44a, 45a with the first to third dielectric films 41 to 43 at both ends of the dicing region 38a increases. Therefore, tolerance to the stress induced by the ablation is achieved. As described above, by use of the machining mask 21f asymmetric to the scanning direction, the diffusion barrier films 44 and 45 are reformed in the region around the dicing region 38a formed by laser beam machining and thus generation of the cracks and peeling for the interlevel dielectric films can be suppressed. After forming the dicing region 38a, the semiconductor substrate 20 is diced to chips by use of a blade having a width narrower than the dicing region. Thus, it is possible to manufacture a semiconductor device in which the peeling and cracks of the interlevel dielectric films are suppressed. Moreover, after dicing the semiconductor substrate 20, steps such as a sealing step and an assembly step are subsequently performed for the obtained semiconductor chips. In this event, a highly reliable semiconductor device is achieved, which prevents peeling and cracking of the interlevel dielectric films from peripheries of the chips.

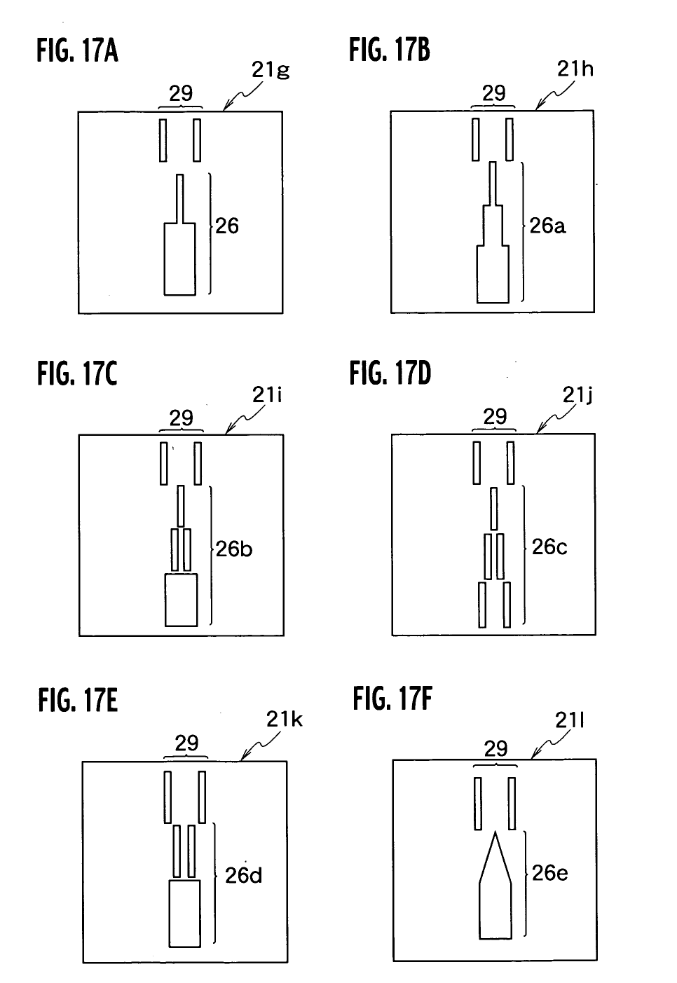

In the above-described explanation, the rectangular region machining opening 26f is used in the machining mask 21f. However, the region machining opening is not limited to a rectangular shape and various shapes are applicable. For example, as shown in FIGS. 17A to 17F, in combination with the region machining openings 26 and 26a to 26e, which are described in the first embodiment, the peeling and cracks of the interlevel dielectric films can be further effectively suppressed. A machining mask 21g of FIG. 17A uses the region machining opening 26 of FIG. 2. Moreover, a machining mask 21h of FIG. 17B uses the region machining opening 26a of FIG. 10A. Furthermore, machining masks 21i to 211 of FIGS. 17C to 17F use the region machining openings 26b to 26e of FIGS. 10B to 10E, respectively.

When the machining masks 21g to 211 shown in FIGS. 17A to 17F are used, the reformed diffusion barrier films 44 and 45 are removed by the region machining openings 26 and 26a to 26e capable of suppressing the generation of cracks of the interlevel dielectric films between the diffusion barrier films 44 and 45. Accordingly, the interlevel dielectric films are removed. Therefore, by reforming the diffusion barrier films 44 and 45 in the region around the dicing region 38a formed by laser beam machining, the cracks and peeling of the interlevel dielectric films can be more efficiently suppressed.

(Third Embodiment)

In a third embodiment of the present invention, by use of the laser beam machining apparatus shown in FIG. 1, not only the interlevel dielectric films but also a semiconductor substrate (object) 20 such as Si is processed. In the first and second embodiments, a method for separating semiconductor devices into chips by dicing the semiconductor substrate 20 by use of a blade is applied after removing the interlevel dielectric films in the upper layers by the laser beam machining method. However, if the semiconductor substrate 20 is diced by use of a blade, the semiconductor substrate 20 of a chip is damaged and cracks are generated therein. The damage and cracks of the semiconductor substrate 20 of a chip decrease chip strength of the semiconductor device. Therefore, along with thinning of the chips, machining technology without damage and cracks is desired.

As the machining method which does not damage the semiconductor substrate 20 and does not generate any cracks, the following two methods are enumerated. One is a wet laser beam machining method which performs laser beam machining while supplying the liquid 13 such as a water to at least a machining region. The other is an ultra-short pulse laser beam machining method which performs laser beam machining by irradiating a laser beam having a pulse width of 1 ps or less. In the wet laser beam machining method, a laser beam having a pulse width of several ns to several tens of ns, such as a krypton fluoride (KrF) excimer laser, the second harmonic of a Q-switch Nd:YAG laser or the third harmonic thereof, can be used. Moreover, in the ultra-short pulse laser beam machining method, for example, a laser beam of the second harmonic of a titanium sapphire laser having a wavelength of 785 nm and a pulse width of approximately 120 fs can be used. In the third embodiment, as the machining light source 2 of the laser beam machining apparatus shown in FIG. 1, the third harmonic of the Q-switch Nd:YAG laser with a wavelength of 355 nm is used.

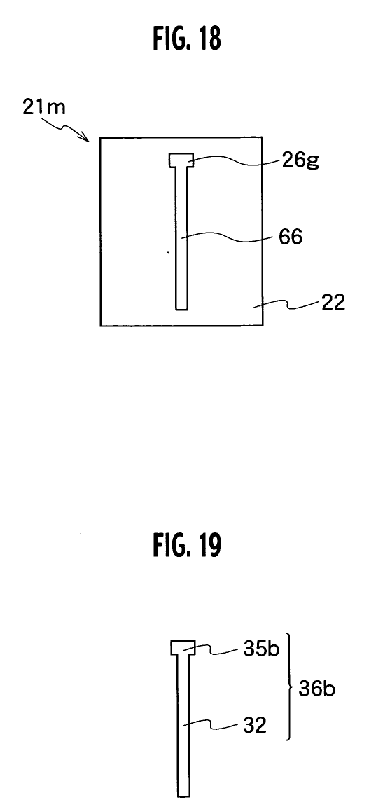

As shown in FIG. 18, a machining mask 21m according to the third embodiment of the present invention has rectangular shaped openings for the region machining opening 26g and a trench machining opening 66 in an opaque portion 22. The trench machining opening 66 is connected to an end of the region machining opening 26g and extends in a direction corresponding to the scanning direction. The trench machining opening 66 is provided so that a trench to be formed is positioned in the center of a dicing region to be formed by the region machining opening 26g. For example, the region machining opening 26g which removes dielectric films has a width of 80 μm in a direction orthogonal to the direction corresponding to the scanning direction and a length of 50 μm. The trench machining opening 66 which processes a dicing trench of the semiconductor substrate 20 has a width of 30 μm in the direction orthogonal to the direction corresponding to the scanning direction and a length of 600 μm.

As shown in FIG. 19, a machining laser beam 36b, that is a projected image of the machining mask 21m on a surface of the semiconductor substrate 20, includes a second region machining laser beam 35b which is a laser beam projected through the region machining opening 26g and a trench machining laser beam 32 which is connected to the second region machining laser beam 35b and extends in the scanning direction. In the third embodiment, an irradiation fluence of the machining laser beam 36b is provided uniformly. However, in accordance with a condition of a dielectric film or an interlevel dielectric film to be processed, the irradiation fluence of the second region machining laser beam 35b can be reduced by use of a light attenuator and the like compared to the irradiation fluence of the trench machining laser beam 32.

In the machining mask 21m according to the third embodiment, a dicing region is provided in a dielectric film on the semiconductor substrate 20 by the second region machining laser beam 35b. Next, by use of the wet laser beam machining method, a dicing trench having a width narrower than the width of the dicing region is formed by the trench machining laser beam 32. Therefore, processing without peeling of the dielectric film or damage and cracking of the semiconductor substrate 20 may be possible.

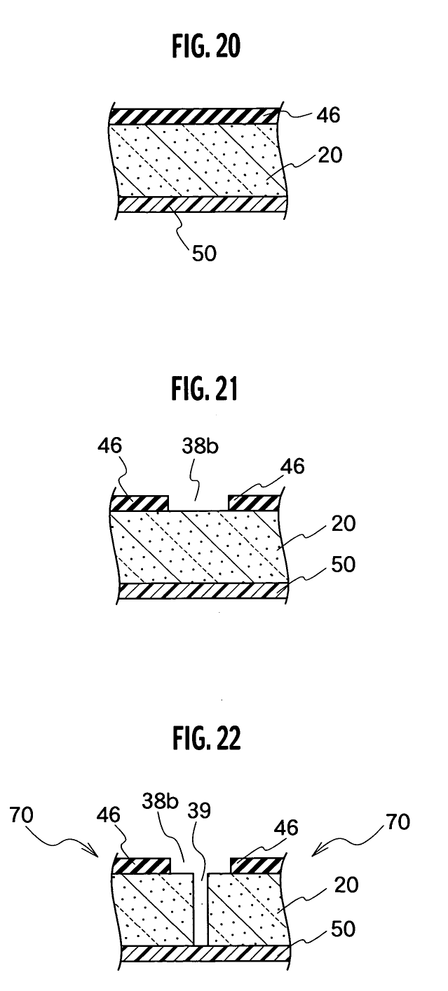

Next, a method for laser beam machining according to the third embodiment will be described with reference to FIGS. 20 to 22. The laser beam has an irradiation fluence, for example, of 2.2 J/cm² and an oscillation frequency of 50 kHz. As an object 20, for simplicity, a semiconductor substrate 20 such as Si having an SiO2 film deposited on a front surface thereof, in which cracks are not generated by the irradiation fluence of trench machining is used. The semiconductor substrate 20 has a thickness of 100 μm. Moreover, a scanning speed of the semiconductor substrate 20 by the scanning system 9 shown in FIG. 1 is 50 mm/s.

As shown in FIG. 20, a dielectric film 46 such as SiO2 is deposited on the front surface of the semiconductor substrate 20. On a rear surface of the semiconductor substrate 20, a dicing tape 50 is provided, by which the semiconductor substrate 20 is fixed on a holder 8 of the laser beam machining apparatus.

Between the semiconductor substrate 20 and the transparent window 7, a liquid 13 such as water is supplied from the liquid supply system 11. The machining laser beam 36b passing through the machining mask 21m provided in the beam shaping unit 4 is irradiated onto the semiconductor substrate 20 through the half mirror 5 and the irradiation optical system 6.

The semiconductor substrate 20 is scanned by the scanning system 9. First, the second region machining laser beam 35b of the machining laser beam 36b causes ablation in the vicinity of the surface of the semiconductor substrate 20 and the dielectric film 46 is selectively removed. Thus, as shown in FIG. 21, a dicing region 38b is formed. Since the second region machining laser beam 35b is as short as 50 μm, the irradiation fluence during scanning the laser beam through the second region machining laser beam 35b is insufficient to form a trench in the semiconductor substrate 20.

The semiconductor substrate 20 is further scanned and the trench machining laser beam 32 causes ablation in a region having a width narrower than a width of the dicing region 38b in the center of the dicing region 38b. The trench machining laser beam 32 is set to 600 μm, which is long enough to provide an irradiation fluence so as to form a trench in the semiconductor substrate 20. When the trench machining laser beam 32 is entirely scanned, as shown in FIG. 22, a dicing trench 39 extending to the rear surface of the semiconductor substrate 20 is formed. Thus, a semiconductor chip 70 is fabricated. Since the liquid 13 is supplied during processing of the dicing trench, dispersion of heat generated by processing can be suppressed. Thus, the dicing trench can be formed which does not damage or crack the layers of the substrate.

As described above, by use of the method for laser beam machining according to the third embodiment, the dicing trench can be formed without peeling of the dielectric film 46 or without the damage and cracks of the semiconductor substrate 20. Thus, the semiconductor chip 70 for a highly reliable semiconductor device can be manufactured.

When a dielectric film having weak adhesion strength or weak mechanical strength, such as a low-k dielectric film, a diffusion barrier film and the like is formed on the semiconductor substrate 20, any shape of the machining masks 21 and 21a to 211 shown in FIG. 2, FIGS. 10A to 10E, FIG. 11 and FIGS. 17A to 17F may be applied. Specifically, a machining mask having an opening asymmetric in the scanning direction is used and an irradiation fluence of each of the regions is controlled in accordance with the dielectric film subjected to reforming for improvement in adhesion strength or removal. Thus, it is possible to perform machining of the dicing trench without peeling and damage of the semiconductor substrate.

(Fourth Embodiment)

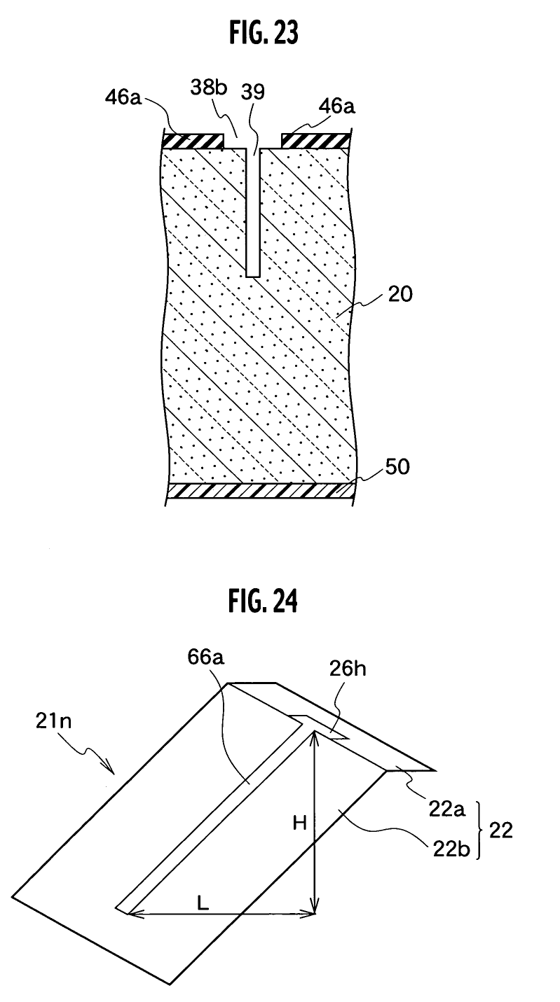

In a method for laser beam machining according to a fourth embodiment of the present invention, description will be given of a case where a semiconductor substrate 20 is thicker than that processed in the third embodiment. When a semiconductor substrate 20 thicker than 100 μm is processed at the same irradiation fluence as that of the third embodiment, even if the scanning speed and the length of the trench machining opening are controlled according to the depth of a trench to be processed, the depth of a processed trench is limited. For example, a thickness of the semiconductor substrate 20 is assumed to be 600 μm. A machining mask is assumed to be the same as the machining mask 21m shown in FIG. 18 except for a length of the trench machining opening. From the result of the third embodiment, the length of the trench machining opening is set to 1800 μm, which is three times longer, and the scanning speed is reduced to half and set to 25 mm/s. The above-described irradiation conditions correspond to an amount of laser beam irradiation six times larger than that of the third embodiment, which is sufficient for laser beam machining of the semiconductor substrate 20 having a thickness of 600 μm. However, as shown in FIG. 23, a dicing trench 39 has a depth of approximately 200 μm and does not extend to a rear surface of the semiconductor substrate 20. Actual measurement of a focal depth of the laser beam machining apparatus shown in FIG. 1 is 200 μm and a marginal depth of machining is limited by the focal depth. Therefore, the semiconductor substrate 20 may have a thickness of 200 μm or less so as to enable a dicing trench to be provided therein by use of a machining mask having a configuration similar to the machining mask 21m. In the fourth embodiment, description will be given of a machining mask and a laser beam machining method for forming a dicing trench in a semiconductor substrate 20 which is thicker than the focal depth of the laser beam machining apparatus.

As shown in FIG. 24, an opaque portion 22 of a machining mask 21n according to the fourth embodiment includes a vertical opaque portion 22a which is disposed vertically to the optical axis, and an inclined opaque portion 22b which is inclined to a plane of the vertical opaque portion 22a. In the vertical opaque portion 22a, a region machining opening 26h (first machining opening) is provided as an opening. In the inclined opaque portion 22b, a trench machining opening 66a (second machining opening) is provided as an opening, which is connected to the region machining opening 26h at an end, which is positioned in a boundary between the vertical opaque portion 22a and the inclined opaque portion 22b, and extends in a direction corresponding to the scanning direction. It is assumed that a length in a direction perpendicular to the vertical opaque portion 22a from the boundary between the vertical opaque portion 22a and the inclined opaque portion 22b to another end of the trench machining opening 66a extending in a direction corresponding to the scanning direction is an opening depth H and a length in a direction parallel to the vertical opaque portion 22a is an opening length L.

The fourth embodiment is different from the third embodiment in that the machining mask 21n having the trench machining opening 66a provided in the inclined opaque portion 22b is used. The rest of the configurations are the same as the third embodiment and thus repetitive description will be omitted.

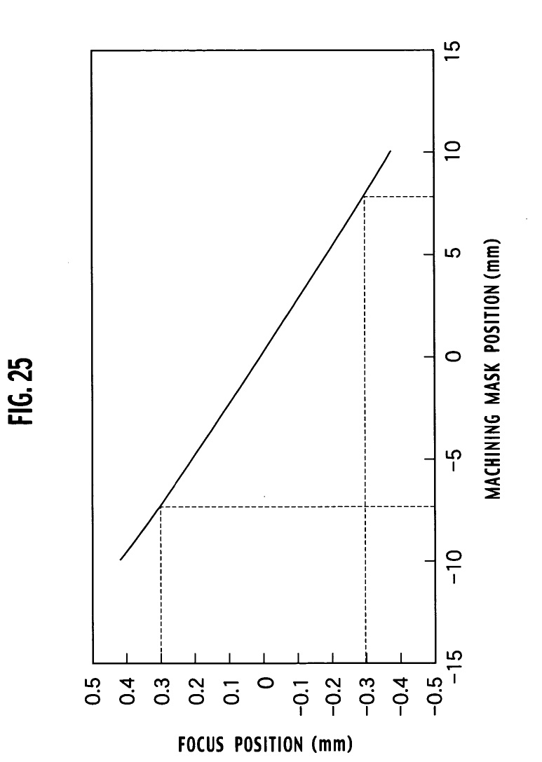

FIG. 25 shows a relationship between a machining mask position along an optical axis in a beam shaping unit 4 of the laser beam machining apparatus shown in FIG. 1 and a focus position of a reduced projection plane orthogonal to the optical axis. As shown in FIG. 25, for example, when the machining mask position shown in the horizontal axis of the drawing is shifted by 15 mm, the focus position of the reduced projection plane shown in the vertical axis of the drawing is shifted by 600 μm. Therefore, by adjusting the opening depth H of the trench machining opening 66a, the focal depth of the laser beam passing through the trench machining opening 66a can be controlled in accordance with the thickness of the semiconductor substrate 20.

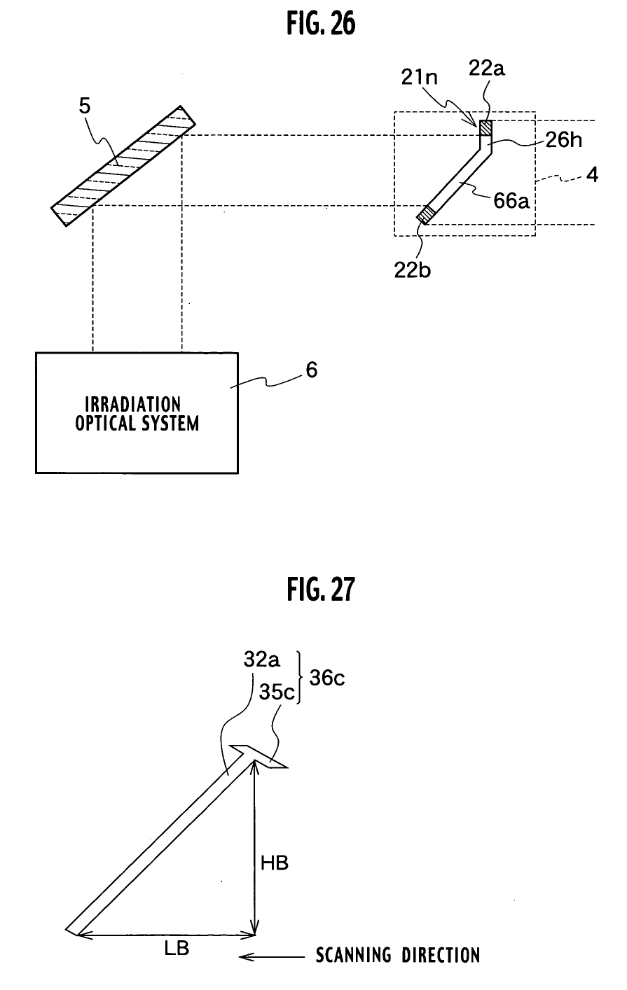

As shown in FIG. 26, the machining mask 21n is disposed in the beam shaping unit 4 so that the vertical opaque portion 22a is positioned perpendicular to the optical axis and an end of an inclined portion of the inclined opaque portion 22b is positioned close to a half mirror 5. The laser beam emitted from the machining mask 21n in the beam shaping unit 4 is irradiated onto the semiconductor substrate 20 on the holder 8 shown in FIG. 1 through the half mirror 5 and the irradiation optical system 6.

As shown in FIG. 27, a machining laser beam 36c projected and imaged from the irradiation optical system 6 includes a second region machining laser beam 35c irradiated on a front surface of the semiconductor substrate 20, and a trench machining laser beam 32a extending in the scanning direction from the second region machining laser beam 35c so as to be inclined with a machining beam length LB and a machining beam depth HB. Specifically, a projected imaging plane of the trench machining laser beam 32a becomes deeper toward a rear surface of the semiconductor substrate 20 from the front surface thereof along the scanning direction. Therefore, processing of a dicing trench is possible for the semiconductor substrate 20 having a thickness of approximately the machining beam depth HB of the trench machining laser beam 32a.

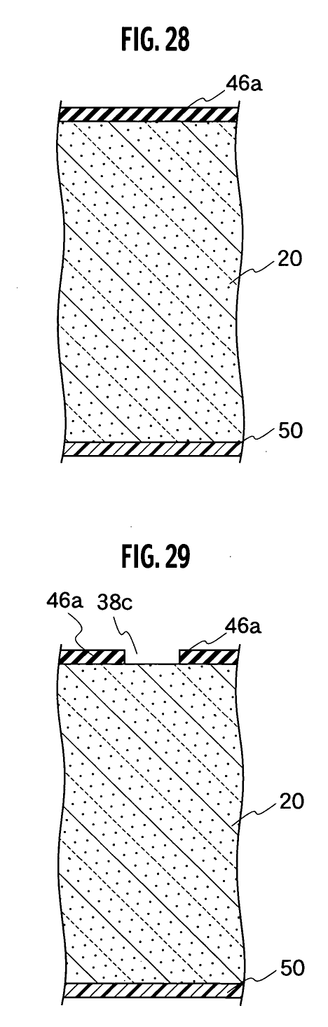

Next, a method for laser beam machining according to the fourth embodiment will be described with reference to FIGS. 28 to 31. The region machining opening 26h of the machining mask 21n has a width of 80 μm in the direction orthogonal to the scanning direction and a length of 50 μm in the scanning direction. Moreover, as to actual dimensions on the machining mask 21n, the opening depth H of the trench machining opening 66a is 15 mm and the opening length L thereof is 9 mm. The trench machining laser beam 32a on the semiconductor substrate 20 has a width of 30 μm in the direction orthogonal to the scanning direction and the machining beam length LB thereof is 1800 μm. Moreover, the machining beam depth HB is adopted to be 600 μm from the relationship shown in FIG. 25. The irradiation fluence of the laser beam is, for example, 2.2 J/cm² and the oscillation frequency is 50 kHz. As an object 20, for simplicity, the semiconductor substrate 20 such as Si having an SiO2 film in which no cracks are generated by the irradiation fluence of trench machining is used. The semiconductor substrate 20 has a thickness of 600 μm. Moreover, a scanning speed of the semiconductor substrate 20 by the scanning system 9 shown in FIG. 1 is 25 mm/s.

As shown in FIG. 28, a dielectric film 46a such as SiO2 is deposited on the surface of the semiconductor substrate 20. On a rear surface of the semiconductor substrate 20, a dicing tape 50 is provided, by which the semiconductor substrate 20 is fixed on the holder 8 of the laser beam machining apparatus.

Between the semiconductor substrate 20 and the transparent window 7, a liquid 13 such as water is supplied from a liquid supply system 11. The laser beam passing through the machining mask 21n provided in the beam shaping unit 4 is irradiated as a machining laser beam 36c onto the semiconductor substrate 20 through the half mirror 5 and the irradiation optical system 6.

The semiconductor substrate 20 is scanned by the scanning system 9. First, the second region machining laser beam 35c of the machining laser beam 36c causes ablation in the vicinity of the front surface of the semiconductor substrate 20 and the dielectric film 46a is removed. Thus, as shown in FIG. 29, a dicing region 38c is formed. Since the second region machining laser beam 35c is as short as 50 μm, no trench is formed in the semiconductor substrate 20.

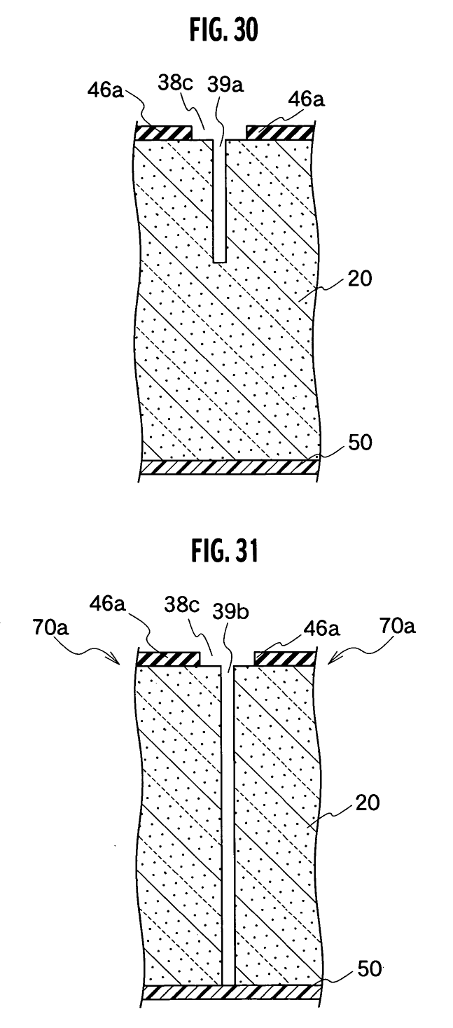

The semiconductor substrate 20 is further scanned and the trench machining laser beam 32a having a width narrower than of the dicing region 38c causes ablation in the center of the dicing region 38c. The machining beam length LB of the trench machining laser beam 32a is provided to be 1800 μm, which is long enough to form a trench in the semiconductor substrate 20. Furthermore, the projected imaging plane of the trench machining laser beam 32a becomes deeper toward the rear surface of the semiconductor substrate 20 in the scanning direction. As shown in FIG. 30, in the middle of the trench machining laser beam 32a, a dicing trench 39a having a depth halfway to the rear surface of the semiconductor substrate 20 from the front surface thereof is formed in a center portion of the dicing region 38c. The machining beam depth HB of the trench machining laser beam 32a is 600 μm, which corresponds to the thickness of the semiconductor substrate 20. Thus, when the trench machining laser beam 32a is entirely scanned on the semiconductor substrate 20, as shown in FIG. 31, a dicing trench 39b extending to the rear surface of the semiconductor substrate 20 is formed. As a result, a semiconductor chip 70a is manufactured. In laser beam machining of the dicing trench 39b, dispersion of heat generated by processing can be suppressed since the liquid 13 is supplied. Consequently, a dicing trench without damage and cracks can be formed in the semiconductor substrate.

In the method for laser beam machining according to the fourth embodiment, the projected imaging plane of the trench machining laser beam 32a becomes deeper toward the rear surface of the semiconductor substrate 20. Therefore, even in the semiconductor device using a thick semiconductor substrate 20, the dicing trench 39b can be formed without peeling of the dielectric film 46a or without damage and cracks of the semiconductor substrate 20. Thus, the semiconductor chip 70a of a highly reliable semiconductor device can be manufactured.

In the fourth embodiment, the region machining opening 26h of the machining mask 21n is provided in the vertical opaque portion 22a so as to be parallel to the front surface of the semiconductor substrate 20. However, the region machining opening 26h may be provided in the inclined opaque portion 22b without providing the vertical opaque portion 22a. In this case, the region machining laser beam is also inclined. However, since an inclined depth of the region machining laser beam is smaller than the focal depth of the laser beam machining apparatus, machining of the dicing region may be possible.

Moreover, when a dielectric film having weak adhesion strength or weak mechanical strength, such as a low-k dielectric film, a diffusion barrier film and the like is formed on the semiconductor substrate 20, it is a matter of course that any shape of the machining masks 21 and 21a to 211 shown in FIG. 2, FIGS. 10A to 10E, FIG. 11 and FIGS. 17A to 17F may be applied, as already mentioned in the first and second embodiments.

(Modification of the Fourth Embodiment)

In a modification of the fourth embodiment of the present invention, description will be given of an irradiation optical system 6 and a laser beam machining method for forming a dicing trench in the semiconductor substrate 20 which is thicker than the focal depth of the laser beam machining apparatus by use of the machining mask 21m described in the third embodiment.

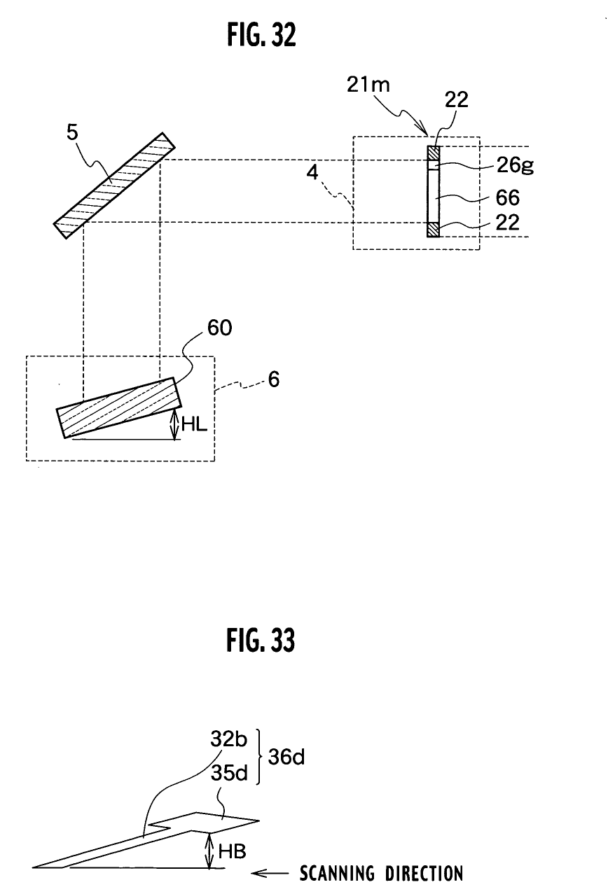

As shown in FIG. 32, in the irradiation optical system 6 according to the modification of the fourth embodiment, an objective lens 60 such as a cylinder lens is placed so that a front portion thereof in the scanning direction is raised to an inclined depth HL. The modification of the fourth embodiment of the present invention is different from the third and fourth embodiments in that the objective lens 60 of the irradiation optical system 6 is provided in an inclined position. The rest of the configurations are the same as the third and fourth embodiments and thus repetitive description will be omitted.

A laser beam passing through the region machining opening 26g and the trench machining opening 66 of the machining mask 21m provided in the beam shaping unit 4 enters the irradiation optical system through the half mirror 5. The inclined objective lens 60 projects a machining laser beam 36d having an inclined imaging plane, as shown in FIG. 33. A second region machining laser beam 35d of the machining laser beam 36d is positioned in a front portion of the scanning direction and an irradiation position of the machining laser beam 36d is inclined deeper along the optical axis from the second region machining laser beam 35d to a trench machining laser beam 32b. For example, an irradiation position of the second region machining laser beam 35d is aligned approximately with the front surface of the semiconductor substrate 20. Accordingly, a position of a projected imaging plane of the trench machining laser beam 32b becomes deeper toward the rear surface of the semiconductor substrate 20 in the scanning direction. By adjusting the inclined depth HL of the objective lens 60, the machining beam depth HB due to the inclined focus position of the objective lens 60 is allowed to coincide with the thickness of the semiconductor substrate 20. Therefore, by use of the machining mask 21m, it is possible to perform machining of a dicing trench in the semiconductor substrate 20 which is thicker than the focal depth of the laser beam machining apparatus.

In the modification of the fourth embodiment, the machining mask 21m is used and, by providing the inclined objective lens 60 of the irradiation optical system 6 the projected imaging plane of the trench machining laser beam 32b becomes deeper toward the rear surface of the semiconductor substrate 20. Therefore, even in the semiconductor device using the thick semiconductor substrate 20, a dicing trench can be formed without peeling of the dielectric film or without damage and cracks of the semiconductor substrate 20. Thus, a semiconductor chip of a highly reliable semiconductor device can be manufactured.

(Fifth Embodiment)

In a fifth embodiment of the present invention, description will be given of laser beam machining for forming a dicing trench in a semiconductor substrate such as GaP and GaN, a sapphire substrate or the like, which has semiconductor light emitting elements fabricated therein. By use of a wet laser beam machining method which performs laser beam machining while supplying a liquid 13 such as water to a processing region or an ultra-short pulse laser beam machining method which performs laser beam machining by irradiation of a laser beam having a pulse width of 1 ps or less, processing can be performed without damaging a object 20 and generating cracks therein.

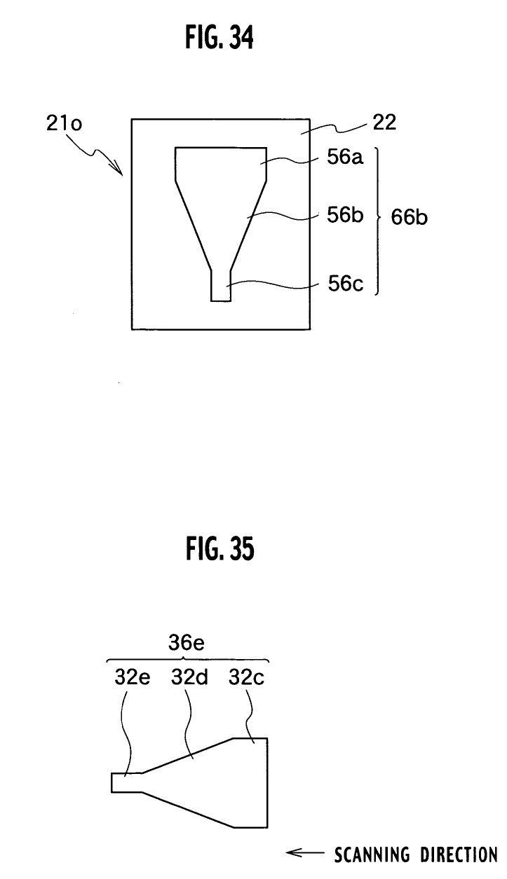

As shown in FIG. 34, a machining mask 21o according to the fifth embodiment has a trench machining opening 66b in an opaque portion 22. The trench machining opening 66b includes openings of a rectangular shaped first transparent portion 56a, a trapezoidal shaped second transparent portion 56b connected to the first transparent portion 56a, and a rectangular shaped third transparent portion 56c connected to a rear portion of the second transparent portion 56b, in a direction corresponding to the scanning direction. Center positions of the first and third transparent portions 56a and 56c in the scanning direction are approximately aligned with each other. A width of the first transparent portion 56a in a direction orthogonal to the scanning direction is wider than that of the third transparent portion 56c. The second transparent portion 56b is provided so that each end of opposed sides of the first and third transparent portions 56a, 56c in a direction orthogonal to the scanning direction are connected with each other.

The machining mask 21o is placed perpendicular to the optical axis in the beam shaping unit 4 shown in FIG. 1. A laser beam having an irradiation fluence sufficient for ablation of the semiconductor substrate 20 passes through the trench machining opening 66b of the machining mask 21o so as to convert a shape of the laser beam. Accordingly, a machining laser beam 36e is projected on the semiconductor substrate 20 through the irradiation optical system 6, as shown in FIG. 35. The machining laser beam 36e includes a rectangular shaped first trench machining laser beam 32c in a front portion of the scanning direction, a trapezoidal shaped second trench machining laser beam 32d which extends so that a width in the direction orthogonal to the scanning direction becomes gradually narrower toward a rear portion in the scanning direction from each end of a rear side of the first trench machining laser beam 32c that is orthogonal to the scanning direction, and a rectangular shaped third trench machining laser beam 32e which is connected to a rear end portion of the trapezoid of the second trench machining laser beam 32d and has the same width as that of the rear end portion of the second trench machining laser beam 32d. Since the semiconductor substrate 20 is scanned, a dicing trench is formed by the first to third trench machining laser beams 32c to 32e of the machining laser beam 36e. Specifically, the dicing trench has sidewalls which are vertical in a vicinity of a front surface of the semiconductor substrate 20, continuously inclined toward a rear surface of the semiconductor substrate 20 and narrow and vertical in a vicinity of the rear surface thereof. The fifth embodiment is different from the first to fourth embodiments in that laser beam machining of the dicing trench is processed by use of the machining mask 21o having a trapezoidal shape in an intermediate region of the opening. The rest of the configurations are the same as the first to fourth embodiments and thus repetitive description will be omitted.

Next, a method for laser beam machining according to the fifth embodiment will be described with reference to FIGS. 36 to 39. As a machining light source 2 of the laser beam machining apparatus shown in FIG. 1, for example, the third harmonic of a Q-switch Nd:YAG laser having a wavelength of 355 nm is used. An irradiation fluence of a laser beam is, for example, 2.2 J/cm² and the oscillation frequency is 50 kHz. As an object 20, a semiconductor substrate 20 such as GaP and GaN is used. The semiconductor substrate 20 has a thickness of 100 μm. A scanning speed of the semiconductor substrate 20 by a scanning system 9 is 50 mm/s.

On a rear surface of the semiconductor substrate 20, as shown in FIG. 36, a dicing tape 50 is provided, by which the semiconductor substrate 20 is fixed on the holder 8 of the laser beam machining apparatus.

Between a front surface of the semiconductor substrate 20 and a transparent window 7, a liquid 13 such as water is supplied from a liquid supply system 11. The laser beam passing through the machining mask 21o provided in a beam shaping unit 4 is irradiated onto the semiconductor substrate 20 through a half mirror 5 and the irradiation optical system 6.

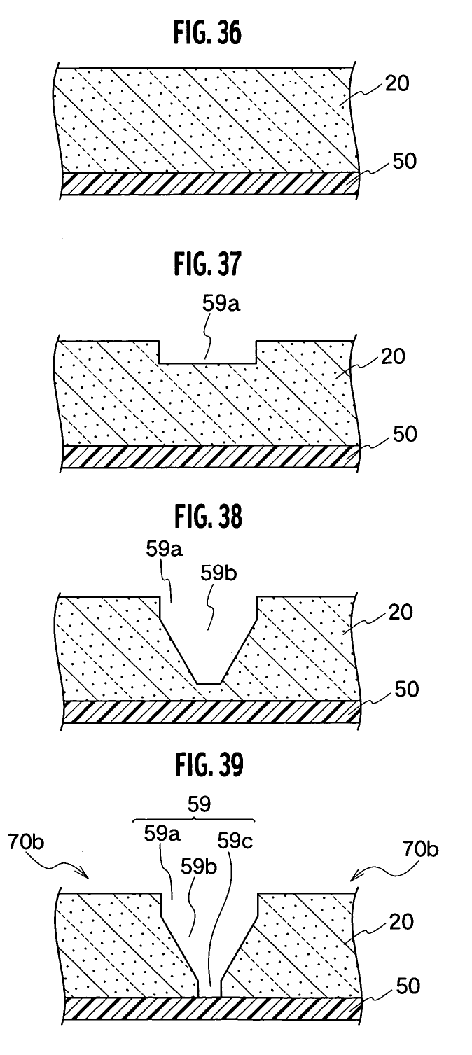

The semiconductor substrate 20 is scanned by the scanning system 9 so as to ablate the semiconductor substrate 20 in the vicinity of the front surface of the semiconductor substrate 20 by the first trench machining laser beam 32c of the machining laser beam 36e. Thus, as shown in FIG. 37, a first dicing trench 59a having approximately vertical sidewalls is formed.

Thereafter, the semiconductor substrate 20 is continuously scanned so as to ablate the semiconductor substrate 20 by the second trench machining laser beam 32d. Thus, as shown in FIG. 38, a second dicing trench 59b having sidewalls formed in a mesa shape corresponding to a projected imaging plane of the trapezoidal shaped second trench machining laser beam 32d, is formed from a bottom of the first dicing trench 59a.

The semiconductor substrate 20 is further scanned so as to ablate the semiconductor substrate 20 by the laser beam passing through the third trench machining laser beam 32e. Thus, as shown in FIG. 39, a third dicing trench 59c having approximately vertical sidewalls is formed from a bottom of the second dicing trench 59b. When the machining laser beam 36e is completely scanned, as shown in FIG. 39, a dicing trench 59 extending to the rear surface of the semiconductor substrate 20 is formed. As a result, a semiconductor chip 70b is fabricated.

According to the fifth embodiment, during processing the dicing trench 59, dispersion of heat generated by processing can be suppressed since the liquid 13 is supplied. Thus, the dicing trench 59 without damage and cracks to the semiconductor substrate 20 can be formed. Since the second transparent portion 56b of the machining mask 21o has a trapezoidal shape, the mesa shaped sidewalls can be formed in the region between the front and rear surfaces of the semiconductor substrate 20. In a semiconductor light emitting element, by providing the mesa shaped sidewalls in a light emitting region, the extraction efficiency of a light can be improved.

Therefore, a wet etching step of removing a damaged layer and a cracked layer is not required after dicing by laser beam machining. Thus, a loss of an effective area and reduction in production yields of the semiconductor light emitting elements can be avoided. Moreover, the mesa shaped sidewalls for improving the luminous efficiency can be formed between electrode formation layers by a single dicing process. Consequently, the semiconductor light emitting elements can be efficiently manufactured.

In the fifth embodiment, the wet laser beam machining method is used for the formation of the dicing trench 59. However, it is needless to say that a method capable of suppressing generation of damage and cracks in the semiconductor substrate 20, for example, an ultra-short pulse laser beam machining method and the like are also applicable. Moreover, in the above-described explanation, the thickness of the semiconductor substrate 20 is set to 100 μm. However, if the thickness thereof is thicker than the focal depth of the laser beam machining apparatus, the objective lens 60 of the irradiation optical system 6 shown in FIG. 32 may be used. Moreover, as described in the fourth embodiment, when the machining mask 21o is inclined in the beam shaping unit 4, it is possible to implement processing of the dicing trench in the semiconductor substrate 20 which is thicker than the focal depth of the laser beam machining apparatus.

(Other Embodiments)

In the first to fifth embodiments of the present invention, the description has been provided using a semiconductor substrate of Si, GaP, GaN or the like as the object 20. However, it is needless to say that other substrates may also be used, including a IV-IV compound semiconductor such as silicon germanium (SiGe) or SiC, and a mixed crystal thereof, a III-V compound semiconductor such as gallium arsenide (GaAs), aluminum gallium arsenide (Al₁₋ₓGaₓAs) or indium aluminum gallium phosphide (In_{1-x-y}Al_{y}GaₓP), and a mixed crystal thereof, a II-VI compound semiconductor such as zinc selenium (ZnSe) or zinc sulfide (ZnS), and a mixed crystal thereof, a sapphire substrate, a SOI substrate, and the like.

Various modifications will become possible for those skilled in the art after receiving the teachings of the present disclosure without departing from the scope thereof.

1. An apparatus for laser beam machining, comprising:
a scanning system configured to move an object in a scanning direction from a first edge of the object to another edge of the object;
a beam shaping unit configured to convert a laser beam to an asymmetrical machining laser beam in the scanning direction on a plane orthogonal to an optical axis of the laser beam; and
an irradiation optical system configured to irradiate the machining laser beam emitted from the beam shaping unit onto the object.

2. The apparatus of claim 1, wherein the beam shaping unit includes a light attenuator which partially attenuates intensity of the machining laser beam.

3. The apparatus of claim 1, wherein the beam shaping unit includes a machining mask inclined in the direction of the optical axis.

4. The apparatus of claim 1, wherein the irradiation optical system includes an objective lens configured to define a focus position inclined in the scanning direction.

5. The apparatus of claim 1, further comprising a liquid supply system configured to supply a liquid to a front surface of the object.

6. A machining mask for converting a shape of a laser beam for laser beam machining of an object by scanning the laser beam on a plane orthogonal to an optical axis of the laser beam, comprising:
an opaque portion having a vertical opaque portion disposed vertically to the optical axis and an inclined opaque portion inclined to a plane of the vertical opaque portion;
a first machining opening which provides an opening in the vertical opaque portion; and
a second machining opening which provides an opening connected to the first machining opening in the inclined opaque portion so as to extend in a direction opposite to the first machining opening.

7. The machining mask of claim 6, wherein the first machining opening has an asymmetric shape in a direction corresponding to a scanning direction of the laser beam.

8. A method for laser beam machining, comprising:
converting a laser beam to an asymmetrical machining laser beam in a first direction;
projecting the machining laser beam onto an object; and
scanning the machining laser beam on a surface of the object in a scanning direction corresponding to the first direction.

9. The method of claim 8, wherein the object is a semiconductor substrate and a dicing trench is formed in the semiconductor substrate by the machining laser beam, the machining laser beam being configured to incline a projected imaging position from a front surface of the semiconductor substrate toward a rear surface thereof in the scanning direction.

10. The method of claim 8, wherein the object is a semiconductor substrate and a dicing trench is formed in the semiconductor substrate by a machining laser beam, the machining laser beam having: a rectangular shaped first trench machining laser beam in a front portion of the scanning direction;
a trapezoidal shaped second trench machining laser beam extending in the scanning direction from each end of a rear side orthogonal to the scanning direction of the first trench machining laser beam; and
a rectangular shaped third trench machining laser beam which has a width same as a width of a rear edge portion of a trapezoid of the second trench machining laser beam and extends in the scanning direction.

11. The method of claim 8, wherein the object is a semiconductor substrate having a dielectric film deposited on a front surface of the semiconductor substrate and the machining laser beam includes in front and rear portions of the scanning direction respectively, a region machining laser beam to form a dicing region by removing the dielectric film and a trench machining laser beam to form a dicing trench in the semiconductor substrate.

12. A method for manufacturing a semiconductor device, comprising:
depositing a dielectric film on a front surface of a semiconductor substrate;
projecting a machining laser beam onto the semiconductor substrate, the machining laser beam being obtained by converting a laser beam to an asymmetric shape in a first direction;
scanning the machining laser beam on the front surface of the semiconductor substrate in a scanning direction corresponding to the first direction; and
forming a dicing region in the scanning direction by removing the dielectric film.

13. The method of claim 12, wherein the dielectric film includes a plurality of interlevel dielectric films having an interconnection and having a diffusion barrier film provided between the interlevel dielectric films, the diffusion barrier films preventing diffusion of a metal contained in the interconnection.

14. The method of claim 13, wherein the interlevel dielectric film has a low dielectric constant.

15. The method of claim 13, wherein the diffusion barrier film is one of silicon carbide, silicon nitride and silicon carbide nitride.

16. The method of claim 12, wherein the machining laser beam removing the dielectric film includes a first region machining laser beam configured to form a narrow dicing region having a width narrower than a width of the dicing region in a front portion of the scanning direction and a second region machining laser beam configured to form the dicing region by enlarging the narrow dicing region formed by the first region machining laser beam, in a rear portion of the scanning direction.

17. The method of claim 13, wherein the machining laser beam removing the dielectric film includes a region machining laser beam configured to form the dicing region and a reforming machining laser beam configured to reform the diffusion barrier film outside of the dicing region in a second direction orthogonal to the scanning direction in a front portion of the scanning direction for the region machining laser beam.

18. The method of claim 17, wherein an energy level of the laser beam of the reforming machining laser beam is reduced compared to the region machining laser beam.

19. The method of claim 16, wherein the machining laser beam further includes a trench machining laser beam extending to a rear portion of the second region machining laser beam in the scanning direction, the method further comprising, processing a dicing trench in a portion of the dicing region in the semiconductor substrate by the trench machining laser beam.

20. The method of claim 19, wherein the dicing trench is formed by use of a machining laser beam having a pulse width of 1 ps or less.

21. The method of claim 12, wherein a liquid is supplied to the front surface of the semiconductor substrate on which the machining laser beam is projected.

22. A semiconductor device, comprising:
a semiconductor substrate;
a plurality of interlevel dielectric films deposited on a surface of the semiconductor substrate; and
a diffusion barrier film deposited between the plurality of interlevel dielectric films and having a region reformed so as to increase adhesion strength between the diffusion barrier film and the interlevel dielectric films in the vicinity of a chip periphery.

23. The semiconductor device of claim 22, wherein the diffusion barrier film is one of silicon carbide, silicon nitride and silicon carbide nitride.

24. The semiconductor device of claim 22, wherein the reformed region includes at least one of amorphous silicon and amorphous carbon.

25. The semiconductor device of claim 22, wherein the interlevel dielectric films have a low dielectric constant.
